(19) United States
(12) Patent Application Publication
(10) Pub. No.: US 2018/0054172 A1
(43) Pub. Date: Feb. 22, 2018

(54) DEVICES AND METHODS RELATED TO ADJUSTING POWER PROVIDED TO POWER AMPLIFIERS

(71) Applicant: SKYWORKS SOLUTIONS, INC., Woburn, MA (US)

(72) Inventors: Sabah KHESBAK, Irvine, CA (US); San CHIN, Yorba Linda, CA (US); Suhanthan RAJENDRA, Foothill Ranch, CA (US)

(21) Appl. No.: 15/220,753

(22) Filed: Jul. 27, 2016

Related U.S. Application Data
(60) Provisional application No. 62/197,441, filed on Jul. 27, 2015.

(51) Int. Cl. H03F 3/195; H03F 1/26; H01L 23/12; H03F 3/213; H03F 3/24; H05K 1/02; H01L 23/66

(52) U.S. Cl. CPC H03F 3/195; H03F 1/26; H01L 23/12; H03F 3/213; H03F 2203/21; H05K 1/0237; H01L 23/66; H03F 2200/451; H03F 3/24

(57) ABSTRACT

Devices and methods related to adjusting power provided to power amplifiers. In some embodiments, a power amplifier (PA) module may include a PA circuit configured to receive a radio-frequency (RF) signal, the PA circuit coupled to a power source. The PA module may also include a voltage module configured to generate a first voltage based on the RF signal. The PA module may further include a comparison module coupled to the voltage module and to the power source, the comparison module configured to adjust an output voltage of the power source based on the first voltage and a second voltage.

### CROSS-REFERENCE TO RELATED APPLICATIONS

This application claims priority to U.S. Provisional Application No. 62/197,441 filed Jul. 27, 2015, entitled “DEVICES AND METHODS RELATED TO ADJUSTING POWER PROVIDED TO POWER AMPLIFIERS,” the disclosure of which is hereby expressly incorporated by reference herein in its respective entirety.

### BACKGROUND

### Field

The present disclosure relates to power amplifiers (PAs) for radiofrequency (RF) applications.

### Description of the Related Art

Power amplifiers may be used in communication networks to set the transmission level of data signals. For example, power amplifiers may be used to set transmission pulse laser energy in optical communication networks. Power amplifiers may be used in radio frequency (RF) components of wireless devices—e.g., base stations and mobile devices—to set the power level transmitted through an antenna. Power amplifiers may also be used in local area networks to support connectivity of servers, computers, laptops, and peripheral devices. Power amplifiers may receive an input RF signal and may amplify the input RF signal to generate an amplified RF signal.

### SUMMARY

In some implementations, the present disclosure relates to a power amplifier (PA) module. The PA module includes a PA circuit configured to receive a radio-frequency (RF) signal, the PA circuit coupled to a power source. The PA module also includes a voltage module configured to generate a first voltage based on the RF signal. The PA module further includes a comparison module coupled to the voltage module and to the power source, the comparison module configured to adjust an output voltage of the power source based on the first voltage and a second voltage.

In some embodiments, the second voltage is indicative of an amount of power to provide to the PA module for a 50 ohm environment.

In some embodiments, the comparison module is configured to adjust the output voltage of the power source by determining whether the first voltage is greater than the second voltage.

In some embodiments, the comparison module is further configured to adjust the output voltage of the power source by increasing the output voltage of the power source when the first voltage is less than the second voltage.

In some embodiments, increasing the output voltage of the power source increases a total radiated power (TRP) of the PA module.

In some embodiments, the comparison module is further configured to adjust the output voltage of the power source by decreasing the output voltage of the power source when the first voltage is greater than the second voltage.

In some embodiments, decreasing the output voltage of the power source decreases a total radiated power (TRP) of the PA module.

In some embodiments, the voltage module comprises a diode and capacitance coupled in series.

In some embodiments, the PA circuit comprises at least one bipolar junction transistor (BJT).

In some embodiments, the PA module further includes a matching network coupled to the PA circuit.

In some embodiments, the PA circuit is coupled to the power source via an inductance.

In some embodiments, the comparison module comprises a comparator.

In some embodiments, the PA module comprises a global system for mobile communications (GSM) PA.

In some embodiments, PA module comprises a multistage PA.

In some embodiments, the PA module further includes a complementary metal-oxide-semiconductor (CMOS) circuit, the CMOS circuit comprising the voltage module and the comparison module.

In some embodiments, the first voltage is indicative of a power of the RF signal.

In some implementations, the present disclosure relates to a method of operating a power amplifier (PA) module. The method includes determining whether a first voltage is greater than a second voltage, the first voltage indicative of a power of a radio-frequency (RF) signal and the second voltage indicative of an amount of power to provide to the PA module for a 50 ohm environment. The method also includes adjusting an output voltage of a power source coupled to the PA module based on the determination.

In some embodiments, the method further includes generating the first voltage based on an RF signal output generated by the PA module.

In some embodiments, adjusting the output voltage of the power source comprises increasing the output voltage of the power source when the first voltage is less than the second voltage.

In some embodiments, increasing the output voltage of the power source increases a total radiated power (TRP) of the PA module.

In some embodiments, adjusting the output voltage of the power source comprises decreasing the output voltage of the power source when the first voltage is greater than the second voltage.

In some embodiments, decreasing the output voltage of the power source decreases a total radiated power (TRP) of the PA module.

In some embodiments, the PA module comprises a global system for mobile communications (GSM) PA.

In some embodiments, the PA module comprises a multistage PA.

In some implementations, the present disclosure relates to a power amplifier (PA) die. The PA die includes a semiconductor substrate. The PA die also includes a PA circuit implemented on the semiconductor substrate, the PA circuit configured to receive a radio-frequency (RF) signal, the PA circuit coupled to a power source. The PA die further includes a voltage module implemented on the semiconductor substrate, the voltage module configured to generate a first voltage based on the RF signal. The PA die further includes a comparison module, implemented on the substrate, the comparison module coupled to the voltage module and to the power source, the comparison module configured to adjust an output voltage of the power source based on the first voltage and a second voltage.

In some implementations, the present disclosure relates to a power amplifier (PA) module. The PA module includes a packaging substrate configured to receive a plurality of components. The PA module also includes a PA circuit formed on a die that is mounted on the packaging substrate, the PA circuit configured to receive a radio-frequency (RF) signal, the PA circuit coupled to a power source. The PA module further includes a voltage module formed on the die, the voltage module configured to generate a first voltage based on the RF signal. The PA module further includes a comparison module formed on the die, the comparison module coupled to the voltage module and to the power source, the comparison module configured to adjust an output voltage of the power source based on the first voltage and a second voltage.

In some implementations, the present disclosure relates to an electronic device. The electronic device includes a transceiver configured to generate a radio-frequency (RF) signal. The electronic device also includes a power amplifier (PA) module in communication with the transceiver and configured to amplify the RF signal, the PA module including a PA circuit configured to receive the RF signal, the PA circuit coupled to a power source, a voltage module configured to generate a first voltage based on the RF signal, and a comparison module coupled to the voltage module and to the power source, the comparison module configured to adjust an output voltage of the power source based on the first voltage and a second voltage. The electronic device further includes an antenna in communication with the PA module, the antenna configured to facilitate transmission of the amplified RF signal.

In some implementations, the present disclosure relates to a method of fabricating a radio-frequency (RF) module. The method includes providing a packaging substrate having a surface, the packaging substrate configured to receive a plurality of components on the surface. The method also includes mounting a power amplifier (PA) circuit on the surface of the packaging substrate. The method further includes mounting a voltage module on the surface of the packaging substrate, the voltage module configured to generate a first voltage based on a RF signal. The method further includes mounting a comparison module on the surface of the packaging substrate, the comparison module configured to adjust an output voltage of a power source based on the first voltage and a second voltage. The method further includes coupling the PA circuit to the voltage module. The method further includes coupling the comparison module to the voltage module.

### BRIEF DESCRIPTION OF THE DRAWINGS

FIG. 1 is a diagram illustrating an example wireless system or architecture having an amplification system, in accordance with some embodiments of the present disclosure.

FIG. 2 is a diagram illustrating an example amplification system, in accordance with some embodiments of the present disclosure.

FIGS. 3A-3E are diagrams illustrating example power amplifiers, in accordance with some embodiments of the present disclosure.

FIG. 4 is a diagram illustrating an example amplification system, in accordance with some embodiments of the present disclosure.

FIG. 5 is a diagram illustrating an example power amplifier (PA), in accordance with some embodiments of the present disclosure.

FIG. 6 is a diagram illustrating an example PA, in accordance with some embodiments of the present disclosure.

FIGS. 7A-7D are diagrams illustrating example PAs on one or more semiconductor dies.

FIG. 8 is a diagram illustrating an example module, in accordance with some embodiments of the present disclosure.

FIG. 9 is a diagram illustrating an example wireless device, in accordance with some embodiments of the present disclosure.

FIG. 10 is a flowchart illustrating an example method of operating a PA, in accordance with some embodiments of the present disclosure.

FIG. 11 is a flowchart illustrating an example method of fabricating a PA, in accordance with some embodiments of the present disclosure.

### DETAILED DESCRIPTION OF SOME EMBODIMENTS

The headings provided herein, if any, are for convenience only and do not necessarily affect the scope or meaning of the disclosure. While pertinent features are illustrated, those skilled in the art will appreciate from the present disclosure that various other features have not been illustrated for the sake of brevity and so as not to obscure more pertinent aspects of the example implementations disclosed herein.

### Introduction:

Power amplifiers may be used in communication networks to set the transmission level of data signals. For example, power amplifiers are used to set transmission pulse laser energy in optical communication networks. Power amplifiers may be used in radio frequency (RF) components of wireless devices—e.g., base stations and mobile devices—to set the power level transmitted through an antenna. Power amplifiers may also be used in local area networks to support connectivity of servers, computers, laptops, and peripheral devices. Power amplifiers may receive an input RF signal and may amplify the input RF signal to generate an amplified RF signal.

A voltage standing wave ratio (VSWR) may be a measure of how well the power amplifier is impedance matched to the circuits and/or transmissions lines that the power amplifier is connected to. For example, the VSWR may indicate how efficiently the power amplifier is able to transmit an RF signal. In another example, the VSWR may indicate how much power is reflected back towards an input of the power amplifier. In one embodiment, the power and/or strength of the amplified RF signal generated by a power amplifier may vary as the VSWR changes. The VSWR may continually change and/or vary when the power amplifier is in operation because of changes in the surroundings of an antenna coupled to the power amplifier. For example, as a user moves a wireless device (which includes the power amplifier and the antenna) the VSWR may change/vary.

Changes in the VSWR may cause the total radiated power (TRP) of the wireless device (e.g., a smartphone, a cellular phone, etc.) to vary as well. For example, if less power is reflected back toward the input of the power amplifier, the power of the RF signal generated or outputted by the power amplifier may increase. This may cause an increase in the TRP of the wireless device. Different standards, standards organizations (e.g., Federal Communications Commission (FCC)), manufacturers (e.g., smartphone manufactures) may restrict/limit the TRP of a wireless device. For example, the FCC may indicate that the TRP of a wireless device may not exceed a threshold TRP. As the VSWR changes/varies, the TRP may increase and may exceed the threshold TRP.

Some of the embodiments, implementations and/or examples described herein may allow a power amplifier to adjust the amount of power provided to the power amplifier by a power source. This may allow the power amplifier to adjust the power of the RF signal generated and/or outputted by the power amplifier. Adjusting the power of the RF signal generated and/or outputted by the power amplifier may help prevent the power amplifier from exceeding the threshold TRP.

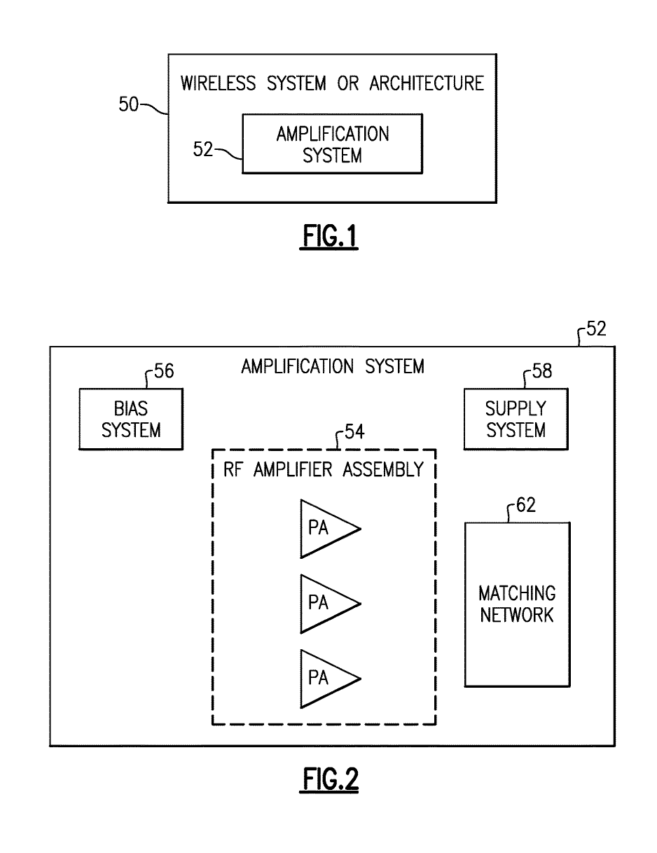

Referring to FIG. 1, one or more features of the present disclosure generally relate to a wireless system or architecture 50 having an amplification system 52. In some embodiments, the amplification system 52 can be implemented as one or more devices (e.g., one or more power amplifiers (PAs)), and such device(s) can be utilized in the wireless system/architecture 50. In some embodiments, the amplification system may be a system (e.g., one or more devices) that increase the power of a signal. For example, the amplification system 52 may convert (e.g., amplify) a low-power radio-frequency signal into a higher-power signal. In some embodiments, the wireless system/architecture 50 can be implemented in, for example, a portable wireless device. Examples of such a wireless device are described herein.

FIG. 2 shows that the amplification system 52 of FIG. 1 typically includes a radio-frequency (RF) amplifier assembly 54 having one or more power amplifiers (PAs). In the example of FIG. 2, three PAs 60a-60c are depicted as forming the RF amplifier assembly 54. It will be understood that other numbers of PA(s) can also be implemented. It will also be understood that one or more features of the present disclosure can also be implemented in RF amplifier assemblies having other types of RF amplifiers.

In some embodiments, the RF amplifier assembly 54 can be implemented on one or more semiconductor die, and such die can be included in a packaged module such as a power amplifier module (PAM) or a front-end module (FEM). Such a packaged module is typically mounted on a circuit board associated with, for example, a portable wireless device.

The PAs (e.g., 60a-60c) in the amplification system 52 are typically biased by a bias system 56. Further, supply voltages for the PAs are typically provided by a supply system 58. In some embodiments, either or both of the bias system 56 and the supply system 58 can be included in the foregoing packaged module having the RF amplifier assembly 54. The bias system 56 and/or the supply system 58 may also include one or more power amplifiers.

In some embodiments, the amplification system 52 can include a matching network 62. Such a matching network can be configured to provide input matching and/or output matching functionalities for the RF amplifier assembly 54.

In some embodiments, the PAs (e.g., 60a-60c) may be multimode multiband (MMMB) PAs. A MMMB PA may allow an electronic devices (e.g., a smartphone, a cellular phone, a table computer, a laptop computer, etc.) to transmit and/or receive signals at different RF frequencies. In other embodiments, the PAs (e.g., 60a-60c) may by global system for mobile communications (GSM) PAs. A GSM PA may a power amplifier that amplifies RF signals for GSM. Although the embodiments, implementations, and/or examples described herein may refer to GSM PAs, it shall be understood that the embodiments, implementations, and/or examples described herein may be applied to other wireless protocols, standards, and/or systems (e.g., Wideband Code-Division Multiple Access (WCDMA), Long-Term Evolution (LTE), etc.).

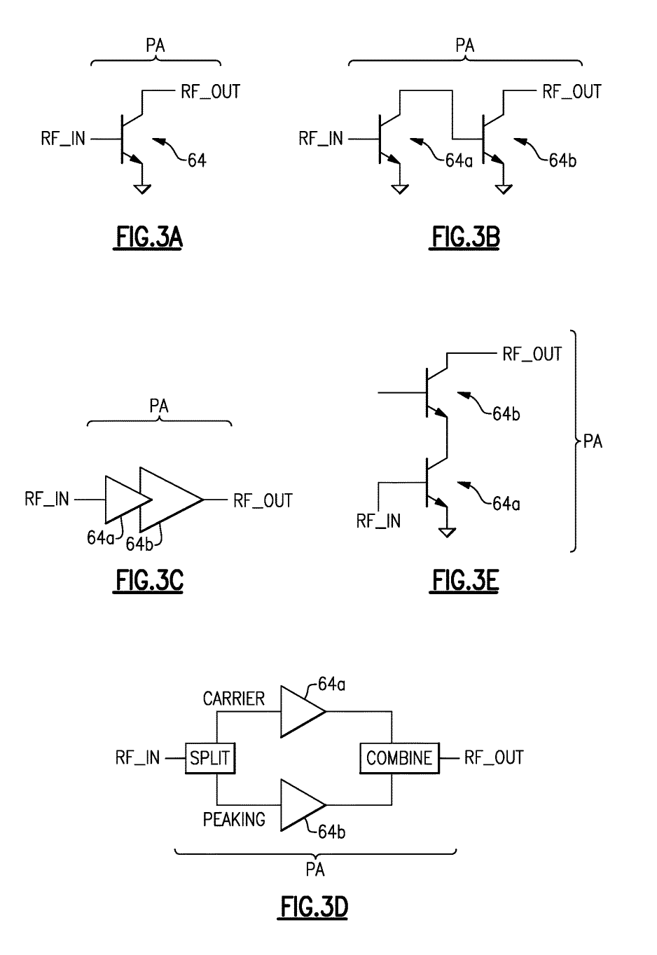

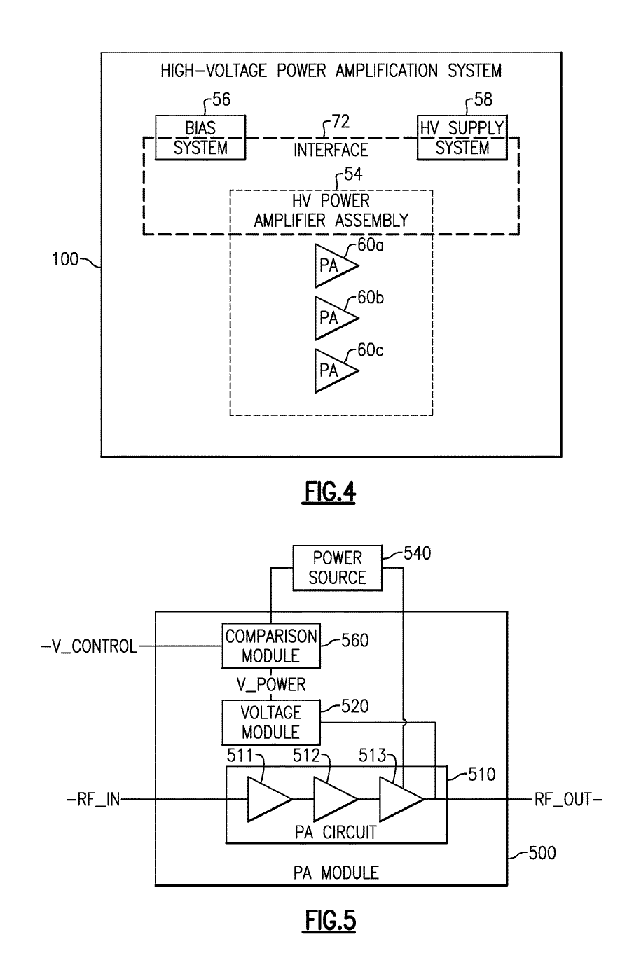

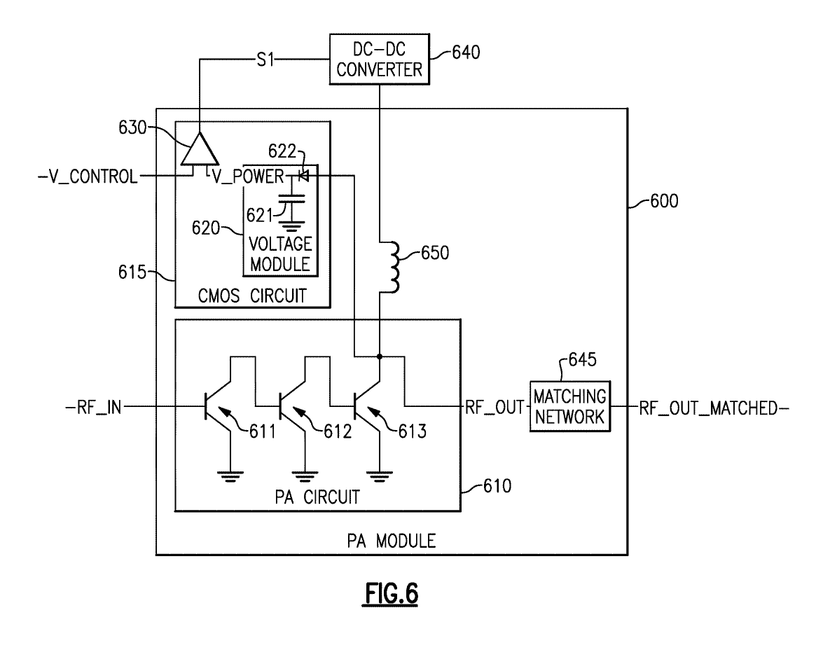

For the purpose of description, it will be understood that each PA (60) of FIG. 2 can be implemented in a number of ways. FIGS. 3A-3E show non-limiting examples of how such a PA can be configured. FIG. 3A shows an example PA having an amplifying transistor 64, where an input RF signal (RF_in) is provided to a base of the transistor 64, and an amplified RF signal (RF_out) is output through a collector of the transistor 64. As discussed above, the PA may be a MMMB PA and/or a GSM PA.

FIG. 3B shows an example PA having a plurality of amplifying transistors (e.g., 64a, 64b) arranged in stages. An input RF signal (RF_in) is provided to a base of the first transistor 64a, and an amplified RF signal from the first transistor 64a is output through its collector. The amplified RF signal from the first transistor 64a is provided to a base of the second transistor 64b, and an amplified RF signal from the second transistor 64b is output through its collector to thereby yield an output RF signal (RF_out) of the PA. As discussed above, the PA may be a MMMB PA and/or a GSM PA.

In some embodiments, the foregoing example PA configuration of FIG. 3B can be depicted as two or more stages as shown in FIG. 3C. The first stage 64a can be configured as, for example, a driver stage; and the second stage 64b can be configured as, for example, an output stage. As discussed above, the PA may be a MMMB PA and/or a GSM PA and/or a GSM PA.

FIG. 3D shows that in some embodiments, a PA can be configured as a Doherty PA. Such a Doherty PA can include amplifying transistors 64a, 64b configured to provide carrier amplification and peaking amplification of an input RF signal (RF_in) to yield an amplified output RF signal (RF_out). The input RF signal can be split into the carrier portion and the peaking portion by a splitter. The amplified carrier and peaking signals can be combined to yield the output RF signal by a combiner. As discussed above, the PA may be a MMMB PA and/or a GSM PA.

FIG. 3E shows that in some embodiments, a PA can be implemented in a cascade configuration. An input RF signal (RF_in) can be provided to a base of the first amplifying transistor 64a operated as a common emitter device. The output of the first amplifying transistor 64a can be provided through its collector and be provided to an emitter of the second amplifying transistor 64b operated as a common base device. The output of the second amplifying transistor 64b can be provided through its collector so as to yield an amplified output RF signal (RF_out) of the PA. As discussed above, the PA may be a MMMB PA and/or a GSM PA.

In the various examples of FIGS. 3A-3E, the amplifying transistors are described as bipolar junction transistors (BJTs) such as heterojunction bipolar transistors (HBTs). It will be understood that one or more features of the present disclosure can also be implemented in or with other types of transistors such as field-effect transistors (FETs).

FIG. 4 shows that in some embodiments, the amplification system 52 of FIG. 2 can be implemented as a high-voltage (HV) power amplification system 70. Such a system can include an HV power amplifier assembly 54 configured to include HV amplification operation of some or all of the PAs (e.g., 60a-60c). As discussed above, one or more of the PAs (e.g., 60a-60c) may be MMMB PAs and/or a GSM PAs. As described herein, such PAs can be biased by a bias system 56. In some embodiments, the foregoing HV amplification operation can be facilitated by an HV supply system 58. In some embodiments, an interface system 72 can be implemented to provide interface functionalities between the HV power amplifier assembly 54 and either or both of the bias system 56 and the HV supply system 58.

FIG. 5 is a block diagram illustrating an example PA 500 according to one embodiment of the present disclosure. The PA 500 is coupled to a power source 540. The PA 500 may be used in various applications and/or configurations within an electronic device (e.g., a smartphone, cellular phone, tablet computer, laptop computer, etc.). For example, the PA 500 may be coupled to various electronic components such as antenna switch modules (ASMs), band switches (BSs), DC/DC converters, bolt on PAs, etc. The PA 500 may receive an input RF signal (RF_in) and may amplify the input RF signal to generate an amplified RF signal (RF_out). The PA 500 includes a PA circuit 510, a voltage module 520, and a comparison module 530. The PA 500 may also be referred to as a PA module and/or an RF module.

The power source 540 may provide power (e.g., a voltage, a current) to one or more components/portions of the PA 500. For example, the power source 540 may provide power to the PA circuit 510. The PA circuit 510 may use the power received from the power source 540 to amplify the input RF signal (RF_in) to generate the amplified RF signal (RF_out). The power source 540 may one or more circuits, modules, components, devices, etc., that may provide power to one or more components/portions of the PA 500. For example, the power source 540 may be a DC-DC converter. The power source 540 is coupled to the PA circuit 510 and the comparison module 530.

In one embodiment, the PA circuit 510 may be one or more circuits, components, modules, devices, etc., that may perform power amplification functions. For example, the PA circuit 510 may receive a lower (e.g., low) power RF signal and may convert the lower power RF signal into a higher (e.g., high) power RF signal. The PA circuit 510 may include multiple stages. For example, the PA circuit 510 may include a first stage 511, a second stage 512 and a third stage 513. The first stage 511 may be an input stage that has high gain and lower power. The second stage 512 may be a driver stage that has medium gain and medium power. The third stage 513 may be an output stage that has low gain and high power. Although three stages are illustrated in FIG. 5, it shall be understood that the PA circuit 510 and/or the PA 500 may include any number of stages in other embodiments. For example, the PA circuit 510 and/or the PA 500 may include two stages. The PA circuit 510 is coupled to the power source 540 and the voltage module 520.

As discussed above the third stage 513 may be an output stage and the output stage may output an RF signal (e.g., a high or higher power RF signal). The voltage module 520 may generate a voltage V_power based on the RF signal RF_out. For example, the voltage module 520 may generate V_power based on the power and/or strength of the RF signal RF_out. The voltage module 520 may generate a higher voltage V_power for a higher power/strength RF signal. The voltage module 520 may also generate a lower voltage V_power for a lower power/strength RF signal. In one embodiment, the voltage module 520 may be one or more one or more circuits, components, modules, devices, etc., that may generate V_power based on the RF signal RF_out. The voltage module 520 may provide V_power (generated based on the RF signal RF_out) to the comparison module 530. The voltage module 520 is coupled to the PA circuit 510 and the comparison module 530. In one embodiment, the voltage module 520 may be coupled to an output of the last stage of the PA 500 (e.g., the third stage 513).

The comparison module 530 is coupled to the voltage module 520. In one embodiment, the comparison module 530 may compare V_power (a first voltage generated by the voltage module 520) with a second voltage (V_control) that may be received from a circuit, component, module, device, etc., that is coupled to the PA 500. In one embodiment, V_control may indicate the amount of power (e.g., voltage) that the power source 540 should provide to the PA 500 (e.g., to the PA circuit 510) in order for the PA 500 to operate within a 50 ohm environment. For example, the power source 540 may use V_control to determine how much power to provide to the PA 500 in order for the PA 500 to operate within the 50 ohm environment. In one embodiment, the VSWR of the 50 ohm environment may be 1:1. For example, no power may be reflected towards the input of the PA 500 in the 50 ohm environment. In another example, the impedance of input of the PA 500 may be matched with the impedance of the output of the PA 500 in the 50 ohm environment.

As discussed above, the VSWR may change and/or vary when the power amplifier is in operation and this may result in the TRP of the PA 500 and/or a wireless device (e.g., a smart phone, a tablet computer, etc.) that includes the PA 500, to exceed a threshold TRP. As the VSWR changes/varies, the V_power may increase or decrease. When V_power increases, this may indicate that the power of the amplified RF signal RF_out (and thus the TRP) is increasing. When V_power decrease, this may indicate that the power of the amplified RF signal RF_out (and thus the TRP) is decreasing.

In one embodiment, the comparison module 530 may cause the power source 540 to increase and/or decrease the amount of power provided to the PA 500 (e.g., provided to the PA circuit 510). For example, the comparison module 530 may cause the power source 540 to increase and/or decrease the voltage (e.g., an output voltage of the power source 540) provided to the PA 500. When V_power is greater than V_control, the comparison module 530 module may cause the power source 540 to decrease the amount of power provided to the PA 500 (e.g., decrease the voltage provided to the PA 500). For example, the comparison module 530 may provide a signal, message, frame, packet, etc., to the power source 540 to indicate that the power source 540 should decrease the amount of power provided to the PA 500. In another example, the comparison module 530 may provide a signal, message, frame, packet, to indicate a lower amount of power (e.g., the signal may indicate a specific voltage that is lower than the current voltage generated by the power source 540). When V_power is less than V_control, the comparison module 530 module may cause the power source 540 to increase the amount of power provided to the PA 500 (e.g., may increase the voltage provided to the PA 500). For example, the comparison module 530 may provide a signal, message, frame, packet, etc., to the power source 540 to indicate that the power source 540 should increase the amount of power provided to the PA 500. In another example, the comparison module 530 may provide a signal, message, frame, packet, to indicate a higher amount of power (e.g., the signal may indicate a specific voltage that is higher than the current voltage generated by the power source 540).

In one embodiment, the comparison module 530 may use V_power and V_control to help optimize the power level of the RF_out signal without exceeding a threshold TRP. For example, when V_power is greater than V_control, this may indicate that the TRP of the PA 500 may have exceeded the threshold TRP. The comparison module 530 may cause the power source 540 to decrease the amount of power provided to the PA 500 such that the RF_out signal does not exceed the threshold TRP. In another example, when V_power is less than V_control, this may indicate that the power level of the RF_out signal may be increased without exceeding the threshold TRP. The comparison module 530 may cause the power source 540 to increase the amount of power provided to the PA 500 which may increase the power level of the RF_out signal. In one embodiment, this may allow the power amplifier to generate the RF_out signal at the maximum power level without exceeding the threshold TRP.

FIG. 6 is a block diagram illustrating an example PA 600 according to one embodiment of the present disclosure. The PA 600 is coupled to a DC-DC converter 640. The PA 600 may be used in various applications and/or configurations within an electronic device (e.g., a smartphone, cellular phone, tablet computer, laptop computer, etc.), as discussed above. The PA 600 may receive an input RF signal (RF_in) and may amplify the input RF signal to generate an amplified RF signal (RF_out). The PA 600 includes a PA circuit 610, a voltage module 620, a comparator 630, an inductance 650, and a matching network 645. The PA 600 may also be referred to as a PA module and/or an RF module.

The DC-DC converter 640 may provide power (e.g., a voltage, a current) to one or more components/portions of the PA 600. For example, the DC-DC converter 640 may provide power to the PA circuit 610. The PA circuit 610 may use the power received from the DC-DC converter 640 to amplify the input RF signal (RF_in) to generate the amplified RF signal (RF_out). The DC-DC converter 640 may one or more circuits, modules, components, devices, etc., that may provide power to one or more components/portions of the PA 600. The DC-DC converter 640 is coupled to the PA circuit 610 via an inductance 650. The DC-DC converter 640 is also coupled to the comparator 630.

In one embodiment, the PA circuit 610 may perform power amplification functions. For example, the PA circuit 610 may receive a lower (e.g., low) power RF signal and may convert the lower power RF signal into a higher (e.g., high) power RF signal. The PA circuit 610 includes bipolar junction transistor (BJT) 611, BJT 612, and BJT 613. BJT 611 may be an input stage that has high gain and lower power. BJT 612 may be a driver stage that has medium gain and medium power. BJT 613 may be an output stage that has low gain and high power. Although three BJTs are illustrated in FIG. 6, it shall be understood that the PA circuit 610 and/or the PA 600 may include any number of BJTs and/or other circuits, modules, components, devices, etc., in other embodiments. The PA circuit is coupled to the DC-DC converter 640 and the voltage module 620.

As discussed above the BJT 613 may be an output stage and the output stage may output an RF signal (e.g., a high or higher power RF signal). The voltage module 620 may generate a voltage V_power based on the RF signal. For example, the voltage module 620 may generate V_power based on the power and/or strength of the RF signals. In one embodiment, the voltage module 620 includes a diode 622 coupled in series to a capacitance 621. The anode of the diode is coupled to the output of the BJT 613 to receive the RF signal RF_out. The cathode of the diode is coupled to the capacitance 621 in series. The diode 622 and the capacitance 621 are coupled to the comparator 630. In one embodiment, the diode 622 and the capacitance 621 may allow the voltage module 620 to generate V_power based on the RF signal RF_out. For example, the diode 622 and the capacitance 621 may allow the voltage module 620 to convert the RF signal RF_out into a voltage (e.g., a DC voltage). In one embodiment, the voltage module 620 may generate a higher voltage V_power for a higher power/strength RF signal and may also generate a lower voltage V_power for a lower power/strength RF signal. The voltage module 620 may provide V_power (generated based on the RF signal) to the comparator 630.

The comparator 630 is coupled to the voltage module 620. In one embodiment, the comparator 630 may compare V_power (a first voltage generated by the voltage module 620) with a second voltage (V_control) that may be received from a circuit, component, module, device, etc., that is coupled to the PA 600. In one embodiment, V_control may indicate the amount of power that the DC-DC converter 640 should provide to the PA 600 (e.g., to the PA circuit 610) in order for the PA 600 to operate within a 50 ohm environment (as discussed above).

As discussed above, the VSWR may change and/or vary when the power amplifier is in operation and this may result in the TRP of the PA 600 and/or a wireless device (e.g., a smart phone, a tablet computer, etc.) that includes the PA 600, to exceed a threshold TRP. As the VSWR changes/varies, the V_power may increase or decrease. When V_power increases, this may indicate that the power of the amplified RF signal RF_out (and thus the TRP) is increasing. When V_power decrease, this may indicate that the power of the amplified RF signal RF_out (and thus the TRP) is decreasing.

In one embodiment, the comparator 630 may cause the DC-DC converter 640 to increase and/or decrease the amount of power provided to the PA 600 (e.g., provided to the PA circuit 610). For example, the comparator 630 may cause the DC-DC converter 640 to increase and/or decrease the voltage (e.g., an output voltage of the DC-DC converter 640) provided to the PA 500. The comparator 630 may compare the voltage V_power with the voltage V_control. When V_control is greater than V_power, the comparator 630 may produce a signal S1 having a logic high state (e.g., a “1”). The signal S1 (having the logic high state) may indicate to the DC-DC converter 640 that the DC-DC converter should increase the amount of power (e.g., increase the voltage) provided to the PA 600 (e.g., the PA circuit 610). When V_control is less than V_power, the comparator 630 may produce a signal S1 having a logic low state (e.g., a “0”). The signal S1 (having the logic low state) may indicate to the DC-Dc converter 640 that the DC-DC converter should decrease the amount of power (e.g., decrease the voltage) provided to the PA 600 (e.g., the PA circuit 610).

In one embodiment, the comparator 630 may use V_power and V_control to help optimize the power level of the RF_out signal without exceeding a threshold TRP. For example, the comparator 630 may cause the DC-DC converter 640 to decrease the amount of power provided to the PA 600 such that the RF_out signal does not exceed the threshold TRP (as discussed above). In another example, the comparator 630 may cause the DC-DC converter 640 to increase the amount of power provided to the PA 600 which may increase the power level of the RF_out signal (as discussed above). In one embodiment, this may allow the PA 600 to generate the RF_out signal at the maximum power level without exceeding the threshold TRP.

As illustrated in FIG. 6, the comparator 630 and the voltage module 620 may be included in a complementary metal-oxide semiconductor (CMOS) circuit 615. The CMOS circuit 615 may be a circuit, device, module, component, etc., implemented using CMOS technology. It shall be understood that in other embodiments, the comparator 630 and the voltage module 620 may be included in and/or may be implemented using other types of circuits.

The PA circuit 610 is coupled to a matching network 645. The matching network 645 may perform impedance matching functions and/or operations for the PA 600. For example, the matching network 645 may provide impedance matching of the output RF signal RF_out with an electrical load (not shown) (e.g., an antenna) to increase or maximize power transfer and/or to reduce or minimize reflections from the load. The matching network 645 may generate the RF signal RF_out_matched based on the RF signal RF_out received from the BJT 613. The matching network 645 may include any combination of circuits, components, modules, devices, etc., that may perform impedance matching functions and/or operations.

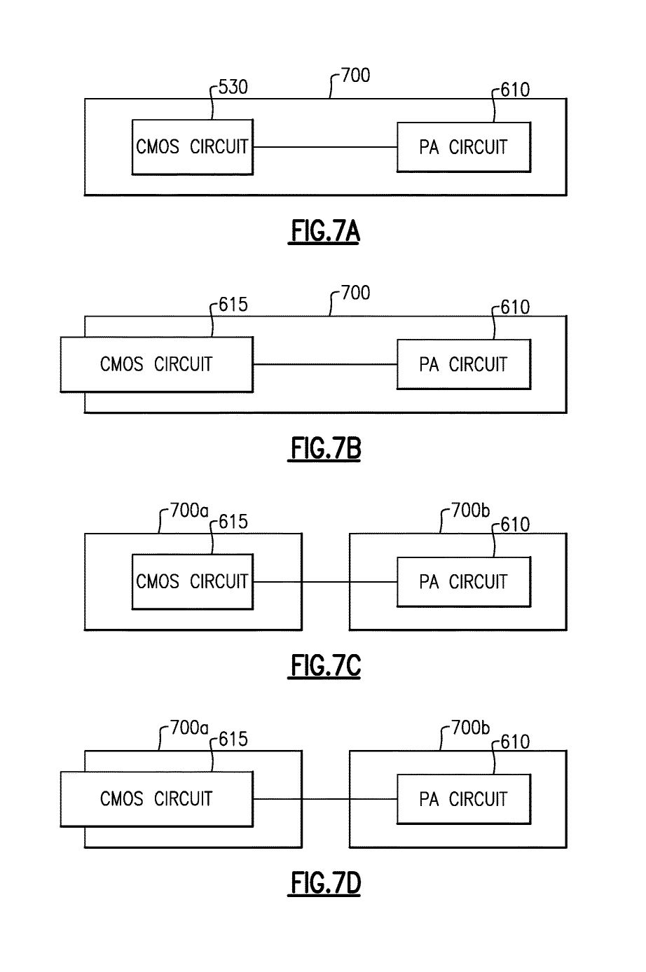

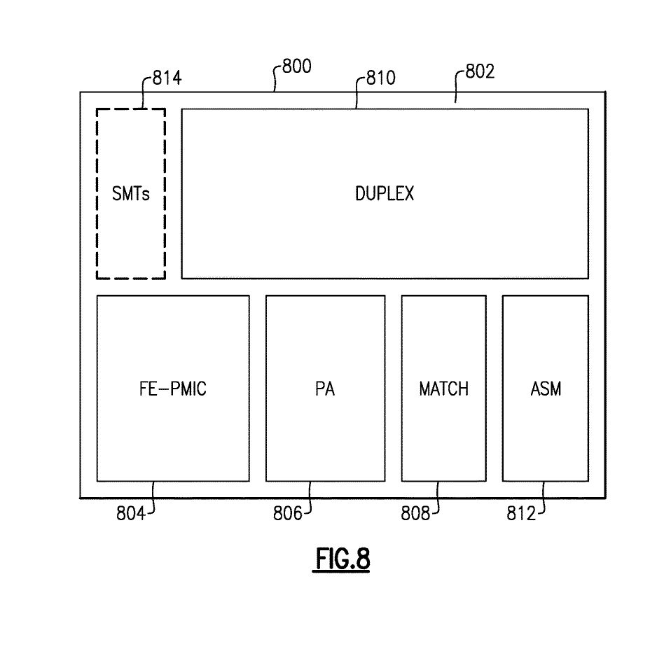

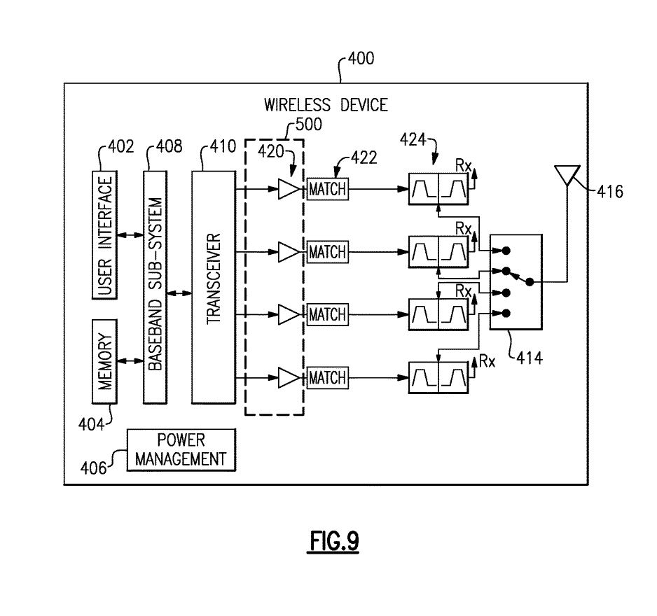

FIGS. 7A-7D schematically show non-limiting examples of implementations/configurations of PAs on one or more semiconductor die. FIG. 7A shows that in some embodiments, a PA circuit 510 and a CMOS circuit 615 having one or more features as described herein can be implemented on a die 700. As discussed above, the CMOS circuit 615 may include a voltage module (e.g., voltage module 520 illustrated in FIG. 5) and/or a comparison module (e.g., comparison module 530 illustrated in FIG. 5). FIG. 7B shows that in some embodiments, at least some of the CMOS circuit 615 can be implemented outside of the die 700 of FIG. 7A. As discussed above, the CMOS circuit 615 may include a voltage module (e.g., voltage module 520 illustrated in FIG. 5) and/or a comparison module (e.g., comparison module 530 illustrated in FIG. 5).

FIG. 7C shows that in some embodiments, a PA circuit 510 having one or more features as described herein can be implemented on a first die 700a, and a CMOS circuit 615 having one or more features as described herein can be implemented on a second die 700b. As discussed above, the CMOS circuit 615 may include a voltage module (e.g., voltage module 520 illustrated in FIG. 5) and/or a comparison module (e.g., comparison module 530 illustrated in FIG. 5). FIG. 7D shows that in some embodiments, at least some of the CMOS circuit 615 can be implemented outside of the first die 700a of FIG. 7C. As discussed above, the CMOS circuit 615 may include a voltage module (e.g., voltage module 520 illustrated in FIG. 5) and/or a comparison module (e.g., comparison module 530 illustrated in FIG. 5).

FIG. 8 shows that in some embodiments, some or all of power amplification systems (e.g., those shown in FIGS. 3A-3E, 4, 5, and 6) can be implemented, wholly or partially, in a module. Such a module can be, for example, a front-end module (FEM). In the example of FIG. 7, a module 800 can include a packaging substrate 802, and a number of components can be mounted on such a packaging substrate 802. For example, an FE-PMIC component 804, a power amplifier assembly 806, a match component 808, and a duplexer assembly 810 can be mounted and/or implemented on and/or within the packaging substrate 802. Other components such as a number of SMT devices 814 and an antenna switch module (ASM) 812 can also be mounted on the packaging substrate 802. Although all of the various components are depicted as being laid out on the packaging substrate 802, it will be understood that some component(s) can be implemented over other component(s).

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

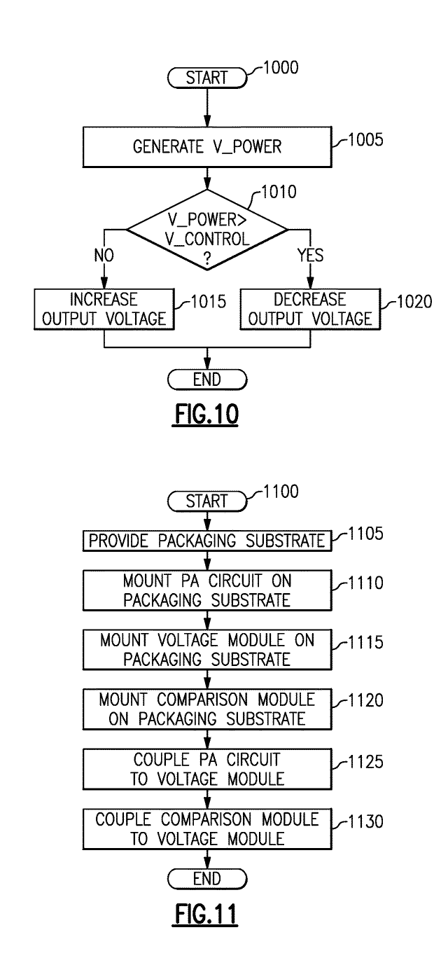

FIG. 9 depicts an example wireless device 400 having one or more advantageous features described herein. In the context of a module having one or more features as described herein, such a module can be generally depicted by a dashed box 500, and can be implemented as, for example, a front-end module (FEM) and/or a PA module.

Referring to FIG. 9, power amplifiers (PAs) 420 can receive their respective RF signals from a transceiver 410 that can be configured and operated in known manners to generate RF signals to be amplified and transmitted, and to process received signals. The PAs 420 may each include a PA circuit, a voltage module, and a comparison module (as discussed above on conjunction with FIG. 5). In one embodiment, the PAs 420 may be MMMB PAs and/or a GSM PA. The transceiver 410 is shown to interact with a baseband sub-system 408 that is configured to provide conversion between data and/or voice signals suitable for a user and RF signals suitable for the transceiver 410. The transceiver 410 can also be in communication with a power management component 406 that is configured to manage power for the operation of the wireless device 400. Such power management can also control operations of the baseband sub-system 408 and the module 500.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 420 are shown to be matched (via respective match circuits 422) and routed to their respective duplexers 424. Such amplified and filtered signals can be routed to an antenna 416 through an antenna switch 414 for transmission. In some embodiments, the duplexers 424 can allow transmit and receive operations to be performed simultaneously using a common antenna (e.g., 416). In FIG. 8, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

As described herein, one or more features of the present disclosure can provide a number of advantages when implemented in systems such as those involving the wireless device of FIG. 9. For example, some of the embodiments, implementations and/or examples described herein may allow a PA (e.g., a PA module) to adjust the amount of power provided to the PA by a power source. This may allow the PA to adjust the power of the RF signal generated and/or outputted by the PA. Adjusting the power of the RF signal generated and/or outputted by the PA may help prevent the PA from exceeding the threshold TRP.

FIG. 10 shows a flowchart representation of a method 1000 of operating a PA (e.g., a PA module). In some embodiments, the method 1000 is at least partially performed by processing logic (such as the voltage module and/or comparison module illustrated in FIG. 5), including hardware, firmware, software, or a combination thereof. In some embodiments, the method 1000 may be partially performed by a processor executing code stored in a non-transitory computer-readable medium (e.g., a memory).

The method 1000 begins, at block 1005, with generating the voltage V_power. For example, the voltage V_power may be generated based on an RF signal outputted and/or generated by the PA (e.g., RF_out illustrated in FIG. 5), as discussed above. At block 1010, the method 1000 includes determining whether V_power is greater than a voltage V_control. As discussed above, V_control may indicate the amount of power that a power source should provide to the PA in order for the PA to operate within a 50 ohm environment. If V_power is not greater than V_control (e.g., V_power is less than V_control), the method 1000 includes increasing the output voltage of a power source and/or causing the output voltage of the power source to be increased (e.g., adjusting the output voltage of the power source) at block 1015, as discussed above. If V_power is greater than V_control, the method 1000 includes decreasing the output voltage of a power source and/or causing the output voltage of the power source to be decreased (e.g., adjusting the output voltage of the power source) at block 1020, as discussed above.

FIG. 11 shows a flowchart representation of a method 1100 of fabricating a PA (e.g., a PA module) having one or more features as described herein. In some embodiments, the PA may be a MMMB PA and/or a GSM PA. In some embodiments, the method 1100 is at least partially performed by processing logic, including hardware, firmware, software, or a combination thereof. In some embodiments, the method 1100 is at least partially performed by a processor executing code stored in a non-transitory computer-readable medium (e.g., a memory).

The method 1100 begins, at block 1105 with providing a packaging substrate. The packaging substrate may include one or more semiconductor dies. At block 1110, the method 1100 includes mounting a PA circuit on the packaging substrate and/or the one or more semiconductor dies. For example, referring to FIG. 5, the PA circuit 510 may be mounted on the packaging substrate and/or the one or more semiconductor dies. At block 1115, the method 1100 includes mounting a voltage module on the packaging substrate and/or the one or more semiconductor dies. For example, referring to FIG. 5, the voltage module 520 may be mounted on the packaging substrate and/or the one or more semiconductor dies. At block 1120, the method 1100 includes mounting a comparison module on the packaging substrate and/or the one or more semiconductor dies. For example, referring to FIG. 5, the comparison module 530 may be mounted on the packaging substrate and/or the one or more semiconductor dies. At block 1125, the method 1100 includes coupling the PA circuit to the voltage module. For example, referring to FIG. 5, the PA circuit 510 may be coupled to the voltage module 520. At block 1130, the method 1100 includes coupling the comparison module to the voltage module. For example, referring to FIG. 5, the comparison module 530 may be coupled to the voltage module 520.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier (PA) module comprising:
a PA circuit configured to receive a radio-frequency (RF) signal, the PA circuit coupled to a power source;
a voltage module configured to generate a first voltage based on the radio-frequency signal; and
a comparison module coupled to the voltage module and to the power source, the comparison module configured to adjust an output voltage of the power source based on the first voltage and a second voltage.

2. The power amplifier module of claim 1 wherein the second voltage is indicative of an amount of power to provide to the power amplifier module for a 50 ohm environment.

3. The power amplifier module of claim 1 wherein the comparison module is configured to adjust the output voltage of the power source by determining whether the first voltage is greater than the second voltage.

4. The power amplifier module of claim 3 wherein the comparison module is further configured to adjust the output voltage of the power source by increasing the output voltage of the power source when the first voltage is less than the second voltage.

5. The power amplifier module of claim 4 wherein increasing the output voltage of the power source increases a total radiated power (TRP) of the power amplifier module.

6. The power amplifier module of claim 3 wherein the comparison module is further configured to adjust the output voltage of the power source by decreasing the output voltage of the power source when the first voltage is greater than the second voltage.

7. The power amplifier module of claim 6 wherein decreasing the output voltage of the power source decreases a total radiated power (TRP) of the power amplifier module.

8. The power amplifier module of claim 1 wherein the voltage module comprises a diode and capacitance coupled in series.

9. The power amplifier module of claim 1 wherein the PA circuit comprises at least one bipolar junction transistor (BJT).

10. The power amplifier module of claim 1 further comprising a matching network coupled to the power amplifier circuit.

11. The power amplifier module of claim 1 wherein the PA circuit is coupled to the power source via an inductance.

12. The power amplifier module of claim 1 wherein the comparison module comprises a comparator.

13. The power amplifier module of claim 1 wherein the PA module comprises a global system for mobile communications (GSM) power amplifier.

14. The power amplifier module of claim 1 wherein the power amplifier module comprises a multistage power amplifier.

15. The power amplifier module of claim 1 wherein the power amplifier module further comprises a complementary metal-oxide-semiconductor (CMOS) circuit, the CMOS circuit comprising the voltage module and the comparison module.

16. The power amplifier module of claim 1 wherein the first voltage is indicative of a power of the radio-frequency signal.

17. A method of operating a power amplifier (PA) module, the method comprising:
determining whether a first voltage is greater than a second voltage, the first voltage indicative of a power of a radio-frequency (RF) signal and the second voltage indicative of an amount of power to provide to the power amplifier module for a 50 ohm environment; and
adjusting an output voltage of a power source coupled to the power amplifier module based on the determination.

18. The method of claim 17 further comprising:
generating the first voltage based on an radio-frequency signal output generated by the power amplifier module.

19. The method of claim 17 adjusting the output voltage of the power source comprises increasing the output voltage of the power source when the first voltage is less than the second voltage.

20. (canceled)

21. The method of claim 17 wherein adjusting the output voltage of the power source comprises decreasing the output voltage of the power source when the first voltage is greater than the second voltage.

22-28. (canceled)
